(19) United States
(12) Patent Application Publication
(10) Pub. No.: US 2007/0290906 A1
(43) Pub. Date: Dec. 20, 2007

(54) Noise-Shaping Device and Method with Improved Lossless Compression and Good Audio Quality for High Fidelity Audio

(75) Inventors: Derk Reefman, Eindhoven (NL); Pieter Joost Adriaan Harpe, Eindhoven (NL); Erwin Janssen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 10/565,929

(22) PCT Filed: Jul. 15, 2004
(86) PCT No.: PCT/IB04/51230

§ 371 Date: Jan. 20, 2006

(30) Foreign Application Priority Data
Jul. 24, 2003 (EP) 03102274.2

(51) Int. Cl. H03M 3/02

(52) U.S. Cl. 341/143

(57) ABSTRACT

Improved sigma-delta modulator (SDM) for 1-bit digital audio noise shaping. It is the object to produce a bit stream that is compatible with the Scarlet Book specification (Super Audio CD standard, SACD) and that achieves a higher lossless compression ratio when compressed and decompressed according to the standard. This goal is achieved by using a trellis-based SDM and/or a prediction filter within the SDM that is similar or identical to the prediction filter in the encoder. The trellis SDM is designed to produce a predicted signal from a range of candidate signals that is as close to the input signal as possible.

The present invention relates generally to a noise-shaping device and method thereof and more specifically, to a noise-shaping device and method thereof with improved compression.

A lossless compression step may be part of the signal processing used to create a Super Audio CD (SACD). The compression step may be used to fit all data on a single disc. The compression may be achieved by any number of conventional algorithms and is commonly referred to as a Direct Stream Transfer (DST). However, due to the fact that the compression is lossless, the user has no influence on the amount of music that will fit on a single SACD. To that end, various conventional techniques for improving the compression ratio by slightly altering the bitstream exist. Unfortunately, the improvements in compression gain have been limited thus far (e.g., 10% improvement) if the signal quality is not to be deteriorated (e.g., maintain a signal-to-noise ratio above 95 dB).

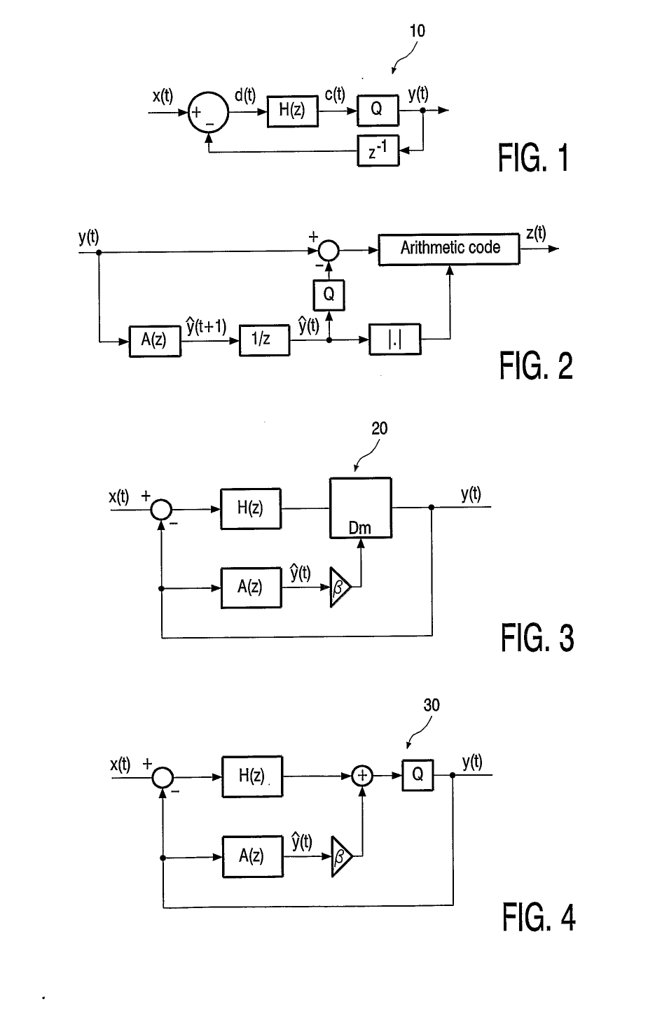

FIG. 1 illustrates a conventional Sigma Delta Modulator (SDM) 10, where c(t) is a representation of the error between the input x(t) and the output y(t). The decision of the sign of the output bit is based solely on the output of the loopfilter H(z).

FIG. 1 illustrates a typical model for a 1-bit SDM. The digital multi-bit input signal x(t) is converted to a single-bit output signal y(t). Signal d(t) is the error signal, including noise and harmonic distortion. c(t) is the frequency weighted error signal. The lowpass transfer function H(z) is responsible for the noise-shaping effect. The device Q is the decision-making unit for the output sequence. In case of a conventional SDM, Q is a 1-bit quantizer with the following definition:

$$y ( t ) = \{ \begin{matrix}+ 1 if c ( t ) \geq 0 \\ - 1 if c ( t ) < 0\end{matrix} \} \qquad ( 1 )$$

In such an implementation, a loop delay z⁻¹ is necessary, otherwise the 1-bit quantizer Q needs to know the value of y(t) before y(t) is actually determined. As a result of this definition, the SDM 10 calculates the output as a function of previous input and output values only. The new output is chosen such that the instantaneous error (c(t)) is as small as possible. However, minimizing the error at each time independently is not necessarily the best solution, neither for the final signal quality, nor for the final entropy of the signal which determines the compression ratio.

An object of the invention is to present a solution that improves the lossless compression performance of a noise-shaping device, while maintaining audio quality.

To this end, the invention provides a noise-shaping device including at least one device for producing an output signal, where the output signal is produced based on an input signal and a predictive signal.

In one or more exemplary embodiments, the predictive signal is produced based on one or more past values of the output signal.

In one or more exemplary embodiments, the at least one device is a decision making device. In one or more exemplary embodiments, the at least one device is a quantizer. In one or more exemplary embodiments, the noise-shaping device further includes a predictive filter for producing a future value of the output signal based on one or more past values of the output signal and supplying the future value of the output signal to the at least one device.

In one or more exemplary embodiments, the predictive filter including a weighting coefficient for weighting the future value of the output signal prior to being input to the at least one device.

In one or more exemplary embodiments, when the weighting coefficient is zero, the output signal of the at least one device is based only on an output of the loop filter.

In one or more exemplary embodiments, when the weighting coefficient is infinitely large, the output signal of the at least one device is based only on an output of the predictive filter.

In one or more exemplary embodiments, the noise-shaping device is a stability-improving device. In one or more exemplary embodiments, the noise-shaping device is a ‘look-ahead’ device. In one or more exemplary embodiments, the noise-shaping device is a sigma-delta modulator (SDM). In one or more exemplary embodiments, the sigma-delta modulator is a trellis sigma-delta modulator or an efficient trellis sigma-delta modulator.

To this end, one or more exemplary embodiments of the invention may provide a trade-off between compressibility of a bitstream, and its signal quality by using a cost function based on both the output of the loopfilter and an output of the prediction filter. When using a trellis-type SDM, the compressibility of the output bitstream can be increased by about 20%, while maintaining good signal quality.

In one or more exemplary embodiments, the trellis sigma-delta modulator minimizes a cost function, which is a function of a loopfilter output, a prediction filter output and a previous output.

In one or more exemplary embodiments, the cost function is represented by

$$C ( t ) = {\sum }_{τ = 0}^{t} {[ c ( τ ) ]}^{2} = C ( t - 1 ) + {[ c ( t ) ]}^{2}$$

where C(t) is the cost function at the current time t, C(t−1) is the cost function at a previous time, and c(t) is an instantaneous error signal.

In one or more exemplary embodiments, the cost function is represented by
C_{T}(t)=C(t)+β·C_{P}(t)

where C_{T}(t) is a total cost function, C_{P}(t) is a current prediction error, and β is a weighting factor.

In one or more exemplary embodiments, the cost function is represented by

$${C}_{P} ( t ) = {\sum }_{τ = 0}^{t} {[ \hat{y} ( τ ) - y ( τ ) ]}^{2} = {C}_{P} ( t - 1 ) + {[ \hat{y} ( τ ) - y ( τ ) ]}^{2}$$

where ŷ(t) is the output of the prediction filter and y(t) the output of the noise shaping device.

In one or more exemplary embodiments, the trellis sigma-delta modulator minimizes a cost function, which is a function of a loopfilter output, a prediction filter output and a previous output.

In one or more exemplary embodiments, the cost function is represented by

$$C ( t ) = {\sum }_{τ = 0}^{t} [ \frac{1 - sign ( \hat{y} \cdot y )}{2} ] with sign ( x ) = \{ \begin{matrix}+ 1 for ( t ) \geq 0 \\ - 1 for ( t ) < 0\end{matrix}$$

To this end, the invention also provides a method comprising receiving an input signal and a predictive signal, weighting the predictive signal, and producing an output signal, based on the input signal and the weighted predictive signal, where the output signal is a function of the input signal and the predictive signal and the predictive signal represents a future value of the output signal based on one or more past values of the output signal.

The present invention will become more fully understood from the detailed description given below and the accompanying drawings, which are given for purposes of illustration only, and thus do not limit the invention.

FIG. 1 illustrates a conventional SDM.

FIG. 2 illustrates a predictive encoding principle in accordance with the conventional art.

FIG. 3 illustrates a noise-shaping device in accordance with an exemplary embodiment of the present invention.

FIG. 4 illustrates a noise-shaping device in accordance with another exemplary embodiment of the present invention.

FIG. 2 illustrates the predictive encoding principle in accordance with the SACD specification (scarlet book). The filter A(z) may be designed to provide an estimate of a future sample ŷ(t+1), based on previous samples y(t−n), . . . , y(t). It is clear that the better this prediction is, the better in general the compression will be. If a bitstream can be generated such, that it is as much as possible, congruent with the predictions of the filter A(z), the compression will increase. In FIG. 2, Q is a conventional 1-bit quantizer, as described above.

FIG. 3 illustrates a noise-shaping device 20 in accordance with an exemplary embodiment of the present invention, where the output y(t) is based on both the output of a loopfilter H(z) and the output of a prediction filter A(z).

When the weighting coefficient β is zero, the decision of the decision-making circuit DM is based on the output of the loopfilter H(z) only, the noise-shaping device 20 is identical to a standard SDM (as shown in FIG. 1). When the weighting coefficient β is infinitely large, the output is based on the prediction filter A(z) only (as result of which the output stream is perfectly compressible but does not accurately represent the input signal x). For intermediate values of β, the noise-shaping device 20 displays the desirable combination of both good signal performance (high signal-to-noise ratio) and good compressibility.

In an exemplary embodiment of the present invention, DM is not the conventional 1-bit quantizer, but rather is implemented as a trellis SDM or an efficient trellis SDM, which generically exhibits the same advantages as a trellis SDM, but requires fewer computations. In exemplary embodiments of the present invention, the trellis SDM or efficient trellis SDM reduce or nimize a cost function. An exemplary algorithm for such a minimization is the trellis viterbi algorithm, hence the name “trellis SDM” for a SDM based on this concept. For a trellis SDM, an exemplary cost function C(t) may be defined as:

$$C ( t ) = {\sum }_{τ = O}^{t} {[ c ( τ ) ]}^{2} = C ( t - 1 ) + {[ c ( t ) ]}^{2} \qquad ( 2 )$$

Applying the concept of FIG. 3 to the concept of a trellis SDM may be achieved by replacing the cost function in Eq. (2) by C_{T}(t):
C_{T}(t)=C(t)+β·C_{P}(t) (3)

where the cost function C_{P}(t) attributes a penalty to an output bit which is not identical to its predicted value (due to A(z)). In principle, there is infinite freedom in the choice of the cost function C_{P}(t). An example is provided in Eq. (4).

$${C}_{P} ( t ) = {\sum }_{τ = 0}^{t} {[ \hat{y} ( τ ) - y ( τ ) ]}^{2} = {C}_{P} ( t - 1 ) + {[ \hat{y} ( τ ) - y ( τ ) ]}^{2} \qquad ( 4 )$$

For the choice made in Eq. (4), the noise-shaping device 20 now is stable for finite β, while displaying good signal characteristics and increased bitstream compressibility. It is noted that many other costs functions could be utilized in place of, or in addition to the one described above, as would be known to one of ordinary skill in the art.

To illustrate the improvements achieved, a bitstream generated by a standard SDM, exhibiting a SNR of 110 dB is considered as an example. This bitstream can be compressed by conventional algorithms by a factor of 2.6. When applying the concept described above, the compression ratio can be increased to a factor of 3.4, while the SNR drops only to 101 dB. Moreover, by choosing a different weighting factor β, a trade-off between compressibility and signal quality can be achieved.

Further variations to the described algorithm include adaptability of the prediction filter A(z), which results in improved performance of the algorithm (at the expense of increased computation).

FIG. 4 illustrates a noise-shaping device 30 in accordance with an exemplary embodiment of the present invention, where the decision-making circuit DM is replaced with an adder and a quantizer Q.

In one or more exemplary embodiments, the noise-shaping device 20 is a stability-improving device. In one or more exemplary embodiments, the noise-shaping device 20 is a ‘look-ahead’ device. In one or more exemplary embodiments, the noise-shaping device 20 is a sigma-delta modulator (SDM). In one or more exemplary embodiments, the sigma-delta modulator is a trellis sigma-delta modulator or an efficient trellis sigma-delta modulator.

As described and illustrated above, the exemplary embodiments of the present invention are directed to digital noise-shaping devices. However, the present invention may also be applied to analog noise-shaping device (either feed back or feed forward). It is further noted that the features of the present invention are usable with many types of noise shapers, SDMs and stability-improving devices, including feedback, feed forward, discrete time, software, hardware, analog, digital, SC-filter, dithered, undithered, low order, high order, single-bit, multi-bit or any combination of these features, as well as other devices such as noise shapers and/or stability-improving devices, either in combination (for example, cascaded) with SDMs and/or other devices or alone.

The principles of the present invention may equally well be applied to multi-bit noise shaping devices. In current, state-of-the-art compression algorithms, prediction filters are employed too, and also in this case generally better compression is achieved when the predictive power of the prediction filter is larger. With the teachings of the present invention, this can be achieved in the same way as described for the single-bit signal by noise-shaping a multi-bit signal such that it fits better to the characteristics of the prediction filter.

It is further noted that the structural and functional features of the various exemplary embodiments described above may be used interchangeably, individually or in combination.

The device according to embodiments of the invention may be included in an ADC and/or DD converter. Such an ADC and/or DD converter may be part of signal processing applications/devices for Super Audio CD (SACD) equipment, e.g. a player.

It is noted that the processing described above is particular useful in the processing of DSD.

It is further noted that the input need not be restricted to a bitstream; the input may be analog or digital. It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claims. The word “comprising” does not exclude the presence of other elements or steps than those listed in a claim. The modifiers “a”, “an”, “one” and “at least one” as used in the appended claims all are intended to include one or more of whatever they modify. The invention can be implemented by means of hardware comprising several distinct elements, and by means of a suitable programmed computer. In a device claim enumerating several means, several of these means can be embodied by one and the same item of hardware. The mere factor that certain measures are recited in mutually different dependent claims does not indicate that a combination of these measures cannot be used to advantage.

1. A noise-shaping device (20, 30) comprising at least one device (DM, Q) for producing an output signal, where the output signal is produced based on an input signal and a predictive signal.

2. The noise-shaping device (20, 30) of claim 1, where the predictive signal is produced based on one or more past values of the output signal.

3. The noise-shaping device (20, 30) of claim 1, wherein the at least one device (DM) is a decision-making circuit.

4. The noise-shaping device (20, 30) of claim 1, wherein the at least one device (Q) is a quantizer.

5. The noise-shaping device (20, 30) of claim 1, further comprising a predictive filter (A(z)) for producing a predicted future value of the output signal based on one or more past values of the output signal and supplying the predicted future value of the output signal to the at least one device (DM, Q).

6. The noise-shaping device (20, 30) of claim 5, the predictive filter (A(z)) including a weighting coefficient (β) for weighting the predicted future value of the output signal prior to being input to the at least one device (DM, Q).

7. The noise-shaping device (20, 30) of claim 6, wherein when the weighting coefficient is infinitely large, the output signal of the at least one device (DM, Q) is based only on an output of the predictive filter (A(z)).

8. The noise-shaping device (20, 30) of claim 1, further comprising a loop filter (H(z)) for providing the input signal, where the input signal is filtered by the loop filter (H(z)).

9. The noise-shaping device (20, 30) of claim 1, wherein the noise-shaping device (20, 30) is a look-ahead sigma-delta modulator.

10. The noise-shaping device (20, 30) of claim 9, wherein the look-ahead sigma-delta modulator minimizes a cost function, which is a function of an output of a loop filter (H(z)), an output of a prediction filter (A(z)) and a previous output.

11. The noise-shaping device (20, 30) of claim 9, wherein the look-ahead sigma-delta modulator is a trellis sigma-delta modulator.

12. The noise-shaping device (20, 30) of claim 11, wherein the trellis sigma-delta modulator minimizes a cost function, which is a function of an output of a loop filter (H(z)), an output of a prediction filter (A(z)) and a previous output.

13. The noise-shaping device (20, 30) of claim 9, wherein the look-ahead sigma-delta modulator is an efficient trellis sigma-delta modulator.

14. The noise-shaping device (20, 30) of claim 13, wherein the efficient trellis sigma-delta modulator minimizes a cost function, which is a function of an output of a loop filter (H(z)), an output of a prediction filter (A(z)) and a previous output.

15. A method, comprising:
receiving an input signal and a predictive signal;
weighting the predictive signal; and
producing an output signal, based on the input signal and the weighted predictive signal, where the output signal is a function of the input signal and the predictive signal and the predictive signal represents a future value of the output signal based on one or more past values of the output signal.
